(19) United States
(12) Patent Application Publication
(10) Pub. No.: US 2013/0088252 A1
(43) Pub. Date: Apr. 11, 2013

(54) METHOD FOR DIAGNOSIS OF CONTACTS OF A PHOTOVOLTAIC SYSTEM AND APPARATUS

(71) Applicant: SMA Solar Technology AG, Niestetal (DE)

(72) Inventors: Ludwig Brabetz, Lehre (DE); Oliver Haas, Kassel (DE); Mohamed Ayeb, Kassel (DE); Gerd Bettenwort, Kassel (DE); Markus Hopf, Espenau (DE); Sebastian Bieniek, Niestetal (DE); Oliver Prior, Marsberg (DE)

(73) Assignee: SMA Solar Technology AG, Niestetal (DE)

(21) Appl. No.: 13/677,685

(22) Filed: Nov. 15, 2012

Related U.S. Application Data
(63) Continuation of application No. PCT/EP2011/058026, filed on May 18, 2011.

(30) Foreign Application Priority Data
May 18, 2010 (EP) 10163130.7
May 18, 2010 (EP) 10163133.1

(51) Int. Cl. G01R 31/26

(52) U.S. Cl. CPC G01R 31/2605
USPC 324/761.01

(57) ABSTRACT

A method for monitoring of contacts of a photovoltaic system includes injection of a test signal having a plurality of frequencies, into the photovoltaic system, and determining a generator impedance of the photovoltaic system by evaluating a response signal associated with the test signal. The method further includes monitoring of contacts of the photovoltaic system independently of operating states of the photovoltaic system by modelling of an alternating-current response of the photovoltaic system based on the determined generator impedance, wherein the modelling is specific to at least two different operating states of the photovoltaic system.

### REFERENCE TO RELATED APPLICATIONS

This application is a continuation of International Application number PCT/EP2011/058026 filed on May 18, 2011, which claims priority to European Application number 10163130.7 filed on May 18, 2010, and European Application number 10163133.1 filed on May 18, 2010.

### FILED

The invention relates to a method and an apparatus for diagnosis, in particular monitoring of contacts, of a photovoltaic system. In particular, the invention relates to a method for monitoring of contacts of a photovoltaic system, which has one or more photovoltaic modules, in order to identify the occurrence of events which adversely affect correct operation of the photovoltaic system.

### BACKGROUND

A photovoltaic system uses photovoltaics to provide electrical energy.

During operation of photovoltaic systems, high electric currents can occur, which in some circumstances, and in conjunction with defective and/or damaged components in the photovoltaic system, can lead to considerable power losses. This relates in particular to contact resistances of contacts of junction points between modules, and to electrical line connections. Contact faults are evident, inter alia, by an increase in the contact resistance of the relevant electrical connection.

DE 10 2006 052 295 B3 describes a method and a circuit arrangement for monitoring of a photovoltaic generator, indicating a fundamental principle for generator diagnosis with signal injection and measurement between a PV generator (=photovoltaic generator) and an inverter. The method is restricted to the night-time hours without solar radiation, in which the inverter does not feed power into the grid system, and there is therefore no flow of current in the direct-current lines of the PV generator.

So far, no satisfactory method and no satisfactory apparatus are known for monitoring contacts of a photovoltaic system.

### SUMMARY

In one embodiment a generator impedance of the photovoltaic system is determined, independently of operating states of the photovoltaic system, for example, by means of a test signal with different frequencies injected into the photovoltaic system. Conclusions relating to the contacts are drawn by modelling of an alternating-current response of the photovoltaic system, based on the generator impedance determined by the test signal.

For this purpose, a method is proposed comprising injecting a test signal, which comprises a plurality of frequencies, into the photovoltaic system, and determining a generator impedance of the photovoltaic system by means of an evaluation of a response signal associated with the test signal. The method further comprises monitoring of contacts of the photovoltaic system independently of operating states of the photovoltaic system by modelling of an alternating-current response of the photovoltaic system, based on the determined generator impedance, wherein the modelling is specific to at least two different operating states of the photovoltaic system.

By considering at least two different operating states in the process of the modelling, it is possible to monitor the photovoltaic system at any time, independently of its operating states. In this case, the operating states may, inter alia, comprise: solar radiation during the daytime, low solar radiation (for example in twilight), no solar radiation during the night-time hours, low and considerable shadowing, full-load, partial-load and no-load states, switched-on and switched-off states, and the like.

The particular advantage in this case is that faults can be identified as soon as they occur, and not only in the night time, when there is no longer any solar radiation.

In one embodiment, the modelling is based on a magnitude and a phase information relating to the determined generator impedance. The phase information relating to the determined generator impedance can be determined from a real part of the generator impedance and an imaginary part of the generator impedance.

The alternating-current response of the photovoltaic system may be modelled using an equivalent circuit. The analytically designed equivalent circuit in this case specifies a circuit which describes the alternating-current response approximately or virtually identically. The equivalent circuit is representative for a functional relationship of the frequency-dependent generator impedance which can be matched to the measured values. Furthermore, it is possible to determine an alternating-current response of the photovoltaic generator by calculation using the characteristic variables of the individual components of the equivalent circuit (resistance, inductance and capacitance values). The photovoltaic system can be monitored based on the characteristic variables determined in this way (or a subset of these characteristic variables), for example with respect to the level of a contact resistance. If the equivalent circuit is chosen skillfully, it is in this case possible for at least one of the characteristic variables of the equivalent circuit to have a value which is substantially independent of operating states of the photovoltaic system. When using a characteristic variable such as this, the monitoring can be carried out reliably and independently of the operating state of the photovoltaic system.

If the supply line is very long, then this can be modelled for high frequencies by adding to the equivalent circuit a further supply-line inductance, a further supply-line resistance and, possibly, a supply-line capacitance arranged between the supply lines.

In this context, it should explicitly be mentioned that the values of the supply-line inductance, of the supply-line resistance and of the supply-line capacitance are not necessarily associated exclusively with the supply line itself, but that the generator, in particular the electrical connections within the generator, can also make a contribution to their values.

The modelling of the alternating-current response of the photovoltaic generator by means of an equivalent circuit can be further improved by the equivalent circuit comprising a combination of a plurality of partial equivalent circuits, with each partial equivalent circuit modelling a part of the photovoltaic system.

For example, a first partial equivalent circuit can model a part of the photovoltaic system which is in a first operating state, and a second partial equivalent circuit can model a second part of the photovoltaic system which is in a second operating state.

By way of example, a temperature influence can be taken into account by at least one partial equivalent circuit comprising a corresponding temperature-dependent component. By way of example, the temperature can additionally be determined by a measurement. Alternatively, the temperature can also be deduced from the alternating-current response, for instance from the characteristic variables which result from the modelling of the response.

Furthermore, when monitoring contacts of the photovoltaic system, an evaluation can be carried out based on expert knowledge, in which case a large number of already known events and their characteristics can contribute to rapid identification of fault states. For example, the expert knowledge may be in the form of a set of rules, in which case the rules can be stored, for example, in a data processing system or its program code.

An apparatus for monitoring of contacts of a photovoltaic system comprises a function generator for generating a test signal with a definable number of partial signals at different frequencies, and an injection device coupled to the function generator for injection of the test signal into the photovoltaic system. The system further comprises a device for determining a frequency-dependent generator impedance of the photovoltaic system from a response signal associated with the test signal, and at least one processing device for identification of parameters, and for monitoring of contacts of the photovoltaic system independent of operating states of the photovoltaic system by modelling of the frequency-dependent generator impedance of the photovoltaic system by performing a method as described above, and comparison with previously defined or previously identified reference values.

The at least one processing device may have an evaluation device for characterization of at least one property which, for example, can be associated with ageing of components and/or degradation of contacts of the photovoltaic system.

In one embodiment, the apparatus is integrated in an inverter in the photovoltaic system, thus resulting in a compact design with simple structure and reliable operation.

The alternating-current response of the photovoltaic system can therefore be described approximately by an equivalent circuit.

In this case, this response is calculated or modelled by determining the associated characteristic variables of the equivalent circuit. The characteristic variables are determined from a test signal injected into the photovoltaic system. In this case, the test signal comprises a plurality of frequencies, thus allowing a frequency response of the photovoltaic system and its generator impedance to be recorded. The information required for modelling, also including any necessary phase information, can be determined from the magnitude, the real part and the imaginary part of this generator impedance.

It is therefore easily possible to obtain all the parameters required for modelling. In this case, the photovoltaic system can be coupled to a grid system in the feed mode, or can be decoupled from it, can be operated on partial load or full load, with solar radiation or shadowed.

In particular, the monitoring is also possible independent of the operating state of the photovoltaic system. Constraints on the photovoltaic system, for example different cell types, operating states, line lengths and the like, can be combined in a simple manner by means of combined partial equivalent circuits to form equivalent circuits, in order to simulate the alternating-current response of the photovoltaic system. This knowledge allows the instantaneous response to be compared with known values, to diagnose the operating state of the system, and thus to identify faults immediately when they occur.

According to one advantageous variant of the method, it is also possible to produce and/or to store and to evaluate recordings of the determined impedance values or characteristic variables over relatively long time periods, in order in this way, for example, to allow degradations and wear or ageing to be identified on the basis of a long-term behaviour.

In one advantageous refinement of the invention, the apparatus including a signal generator and a control device can be integrated in the housing of the inverter, although it is likewise feasible for these components to be arranged entirely or partially outside the housing of the inverter.

### BRIEF DESCRIPTION OF THE DRAWINGS

The invention will be described in more detail in the following text with reference to the attached drawings, in which:

FIG. 1 shows an example of a block diagram of an electrical system having a photovoltaic system, in order to explain how the generator impedance is determined;

FIG. 2 shows an example illustration, in the form of a diagram, of a measured and modelled magnitude of a generator impedance as a function of a frequency;

FIG. 3 shows an example of a first equivalent circuit;

FIG. 4 shows an example of a second equivalent circuit;

FIG. 5 shows an illustration as an example of the circuitry of cells/modules in different operating states, with associated equivalent circuits;

FIG. 6 shows an example of a third equivalent circuit;

FIGS. 7a-7d show example illustrations, in the form of diagrams, of measured values and modelled values of a generator impedance as a function of a frequency in various operating states;

FIG. 8 shows an example of a block diagram of an electrical system having a photovoltaic system, with one example embodiment of an apparatus according to the invention;

FIG. 9a shows an example of a block diagram of an electrical system having a photovoltaic system, with a further example embodiment of an apparatus according to the invention;

FIG. 9b shows an example of a further equivalent circuit;

FIG. 10 shows a flow chart of a method according to the invention;

FIG. 11 shows a schematic voltage/time diagram with various frequencies;

FIG. 12 shows an diagram of measured and calculated values of a profile of an impedance of a series resonant circuit as a function of a frequency;

FIG. 13 shows an example of a precision rectifier with a level-matching circuit;

FIG. 14 shows an example of a neural network for providing temperature compensation for a resistance value;

FIG. 15 an example of a diagram of a measured and compensated time profile of a resistance value; and

FIG. 16 shows a diagram of discrete resistance values measured during simulated contact faults.

### DETAILED DESCRIPTION

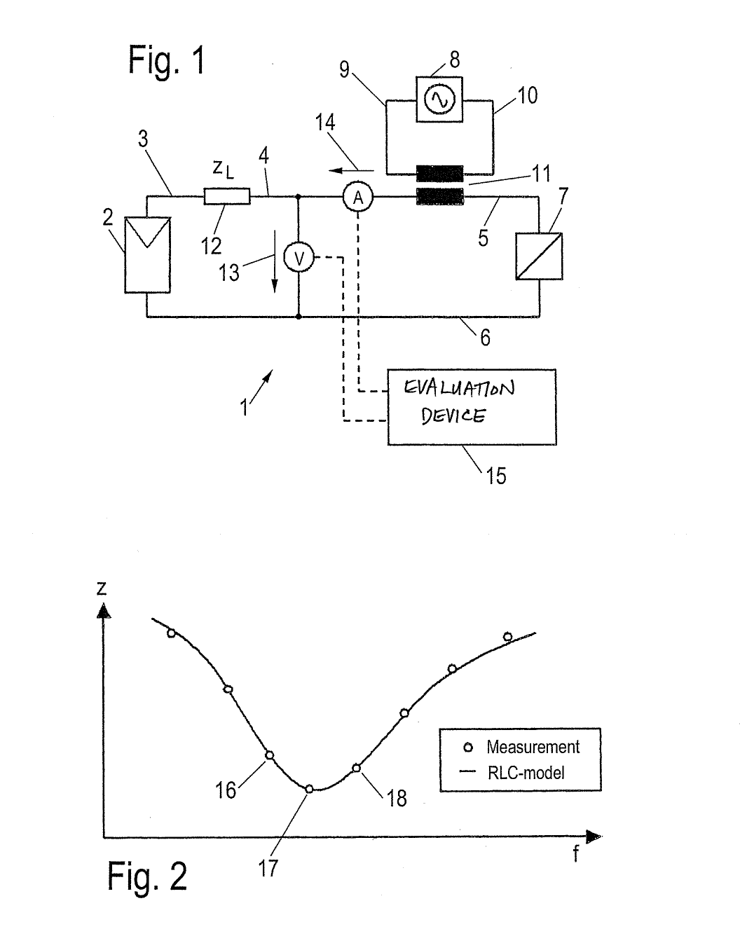

FIG. 1 shows an example of a block diagram of an electrical system, which includes a photovoltaic system 1 comprising at least one photovoltaic module 2, in order to explain how the generator impedance is determined.

The photovoltaic module is connected to an inverter 7 via electrical lines 3, 4, 5, 6. The term PV generator, which is used in the following text, refers to all of the photovoltaic elements of the photovoltaic system 1, which convert radiation to electrical energy, as well as their supply line. In the present FIG. 1, the PV generator for this purpose has the photovoltaic module 2. The figure also shows a function generator 8, which is configured to produce a test signal and is connected via electrical lines 9, 10 to an injection device 11, for example a transformer, which is configured to inject the test signal into the direct-current circuit of the photovoltaic system 1. The illustration also shows an impedance Z_{L} 12, which represents the supply-line impedance of the PV generator 2.

In order to monitor the direct-current circuit of the photovoltaic system 1, a test signal which has a number of partial signals at a different frequency is produced by the function generator 8 and is fed into the direct-current circuit via the injection device 11. During a measurement cycle, the frequency of the partial signals is increased in steps or continuously, for example in the range from about 10 to 1000 kHz, thus producing a test signal with a number of, for example, sinusoidal oscillation excitations, whose frequency increases or decreases in steps. Starting from an oscillation excitation at a minimum frequency, the instantaneous value of a measured voltage 13, which is present at the PV generator, and a measured current 14 flowing in the direct-current circuit (in this case, the measured voltage 13 and the measured current 14 are each components of a response signal from the photo-voltaic system 1 associated with the test signal) are measured and stored for each frequency step by means of a measurement and evaluation device 15. Furthermore, the frequency of the test signal is also detected and stored for each voltage and current measurement point. The frequency range covered is, of course, matched to the properties of the photovoltaic system 1 to be monitored. The measurement and evaluation device 15 uses the stored voltage and current values for each frequency, which is likewise stored, of the test signal to calculate or model a complex-value generator impedance Z_{PV}. The complex-value generator impedance Z_{PV} is in this case determined using methods known from the prior art. This therefore results in a magnitude of the generator impedance Z_{PV} associated with the respective input frequency f. In this context, FIG. 2 shows an example of an illustration, in the form of a diagram, of a measured and modelled magnitude of the generator impedance Z_{PV}. In this case, the circles represent measured values and the solid line represents the modelled profile of the magnitude of the generator impedance |Z|.

An equivalent circuit in the form of a series resonant circuit (a series circuit comprising a resistance R, a coil L and a generator capacitor C) is used to calculate the resistance R (which forms a characteristic variable for monitoring of the direct-current circuit) within the generator impedance Z_{PV}. The values for R, L and C for the chosen equivalent circuit can now be determined from three measured values for the magnitude of the generator impedance |Z| 16, 17, 18 and the associated frequency values. The constraints required for this purpose and the calculation rules are known by those skilled in the art, and will therefore not be explained in any more detail.

The described test signal is applied continually, possibly at specific time intervals, to the photovoltaic system 1. During the process, the profile of the variable R determined using the described procedure is observed. If R increases above a specific limit value, then it is deduced that an excessively high contact resistance has occurred.

It should also be noted that the circular data points in FIG. 2 originate from measurements on a photovoltaic system 1, while the values on the solid line originate from a calculation using an equivalent circuit, whose data for R, L and C has been determined as described above.

Furthermore, the profile, as illustrated in FIG. 2, of the magnitude of the generator impedance |Z| is obtained only during twilight and night-time hours, that is to say without solar radiation into the photovoltaic system 1.

An equivalent circuit of the photovoltaic system 1, which is used as the basis for evaluation, is therefore matched to a number of type-dependent factors and/or to a number of factors which are dependent on the operating mode.

Type-dependent factors of the photovoltaic system 1 in the following text mean, inter alia: a supply-line length, a module type of a photovoltaic module 2, a cell type of a photovoltaic module 2, a number of cells in a photovoltaic module 2, a type of circuitry, a number of photovoltaic modules in a string, or a number of strings in a PV generator.

Factors which are dependent on the operating mode in the following text mean, inter alia, solar radiation onto a PV generator or onto a part of a PV generator, a temperature of a PV generator or a temperature of a part of a PV generator, or an operating point of a PV generator or of a part of a PV generator.

It should be noted that, in the present context, equivalent circuits are used to model the alternating-current response (that is to say the response when stimulated with an alternating-current test signal) of a PV generator or of a part of a PV generator. One or more characteristic values are then determined from the chosen equivalent circuit, by means of suitable calculation and evaluation methods, from the detected measured values, in which case a characteristic value of an equivalent circuit means a value of a component, for example of a resistor R. The determined characteristic value or values is or are then used to identify the occurrence of an event which disadvantageously affects correct operation of a photovoltaic system 1. In consequence, the functional relationship of the frequency-dependent impedance can be modelled mathematically exactly, corresponding to the equivalent circuit, thus making it possible to determine all the characteristic variables in the equivalent circuit (resistances, inductances, capacitances). However, alternatively, an approximation formula, which is sufficiently accurate for the frequency range used in the measurement, can also be used, by means of which, if required, it is possible to determine explicitly only some of the characteristic variables in the equivalent circuit, for example only the characteristic variables which are relevant for monitoring of the PV generator, such as a resistance value. This makes it possible to considerably reduce the computational complexity for determination of the characteristic variables.

Various embodiments for adaptation of an equivalent circuit will be explained in the following text.

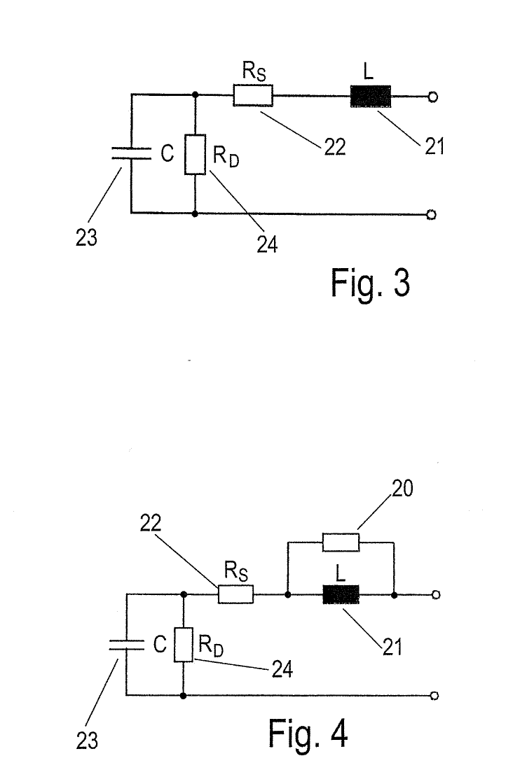

FIG. 3 shows a first equivalent circuit for modelling the electrical alternating-current response of a PV generator or of a part of a PV generator (cell, photovoltaic module 2), if all the parts of the PV generator are in virtually the same operating state. This means that all the parts of the PV generator under consideration are, for example, subject to the same temperature and/or the same solar radiation. In this case, the equivalent circuit comprises a generator capacitance C 23, which is connected in parallel with a generator resistance R_{D} 24. These elements are in turn followed by a series resistance R_{S} 22 and a supply-line inductance L 21. As is shown in FIG. 4, the supply-line inductance L 21 can optionally also be connected in parallel with a further supply-line resistance 20.

In the two equivalent circuits shown in FIG. 3 and FIG. 4, the parallel circuit comprising the supply-line inductance L 21 and the supply-line resistance 20 models the inductive response of a (long) supply line, and of the electrical connections within the PV modules. The series resistance R_{S} 22 models the resistive series component of the PV modules and of their supply lines, and includes a component which is associated with the contact resistances of the various electrical contact points within the PV modules and for their supply lines. The parallel circuit comprising C 23 and R_{D} 24 can be mainly associated with the response of the PV modules.

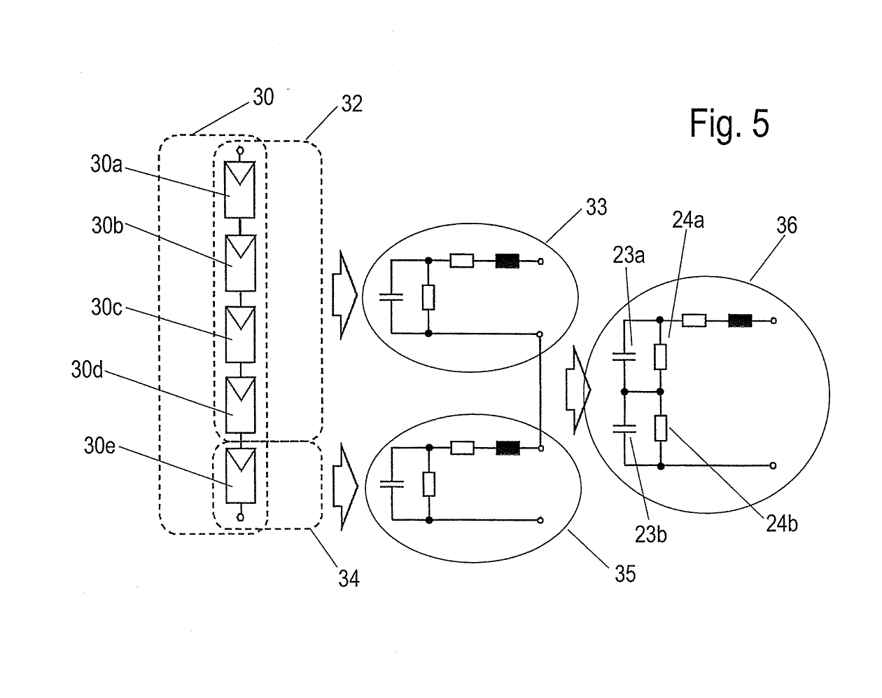

FIG. 5 shows an example of an illustration of the circuitry of cells/modules in different operating states with associated equivalent circuits, and shows a photovoltaic generator 30 (PV generator) in the form of five cells 30a to 30e connected in series. The cells 30a to 30e are cells of the same type. In other words, the cells 30a to 30e have the same type-dependent factors. The cells 30a to 30d are in the same operating state (for example these cells are subject to the same solar radiation or are at the same temperature), or in other words the cells 30a to 30d have the same factors which are dependent on the operating mode, and form a first cell group 32. The cell 30e is in a different operating state (for example it is subject to different solar radiation or is at a different temperature), and forms a second cell group 34.

Investigations for the purposes of the present invention have shown that the alternating-current response of the first cell group can be modelled by a first partial equivalent circuit 33, and that of the second cell group can be modelled by a second partial equivalent circuit 35, with the partial equivalent circuits being connected in series, and each corresponding to one of the equivalent circuits as described in FIG. 3 and FIG. 4. The two partial equivalent circuits 33, 35 can in this case be combined to form a combined equivalent circuit 36, which in each case contains only one series resistance and only one supply-line inductance. The number of pairs of parallel-connected generator capacitances 23a, 23b and generator resistances 24a, 24b in this case once again corresponds to the number of cell groups which are contained in the combined equivalent circuit 36.

Furthermore, the combined equivalent circuit 36 can be further simplified to an equivalent circuit as shown in FIG. 3 or FIG. 4 when the first cell group and the second cell group are in an identical operating state.

In this case, when two or more partial equivalent circuits are combined to form a combined equivalent circuit, the values of the individual components in the individual partial equivalent circuits must be adapted.

At the same time, in one application of the method according to the invention, it is possible to diagnose the state of the photovoltaic system 1 based on the decision as to whether two or more partial equivalent circuits, one combined equivalent circuit, or one equivalent circuit as shown in FIG. 3 or FIG. 4 lead or leads to a sufficiently accurate description of the alternating-current response of the photovoltaic system 1. For example, the presence and the extent of shadowing of the cells in the photovoltaic generator 30 can be identified in this way.

At this point, it should be noted that the splitting of the cells into cell groups may be not only a result of the operating conditions, but may also be dependent on the design type. For example, if a PV module in a photovoltaic generator 30 is replaced by a new PV module which is different from the other modules, it may also be necessary to split the photovoltaic generator 30 into cell groups with associated partial equivalent circuits, in order to model the alternating-current response as accurately as possible. In this situation, it is normally impossible to combine the partial equivalent circuits themselves in identical operating conditions.

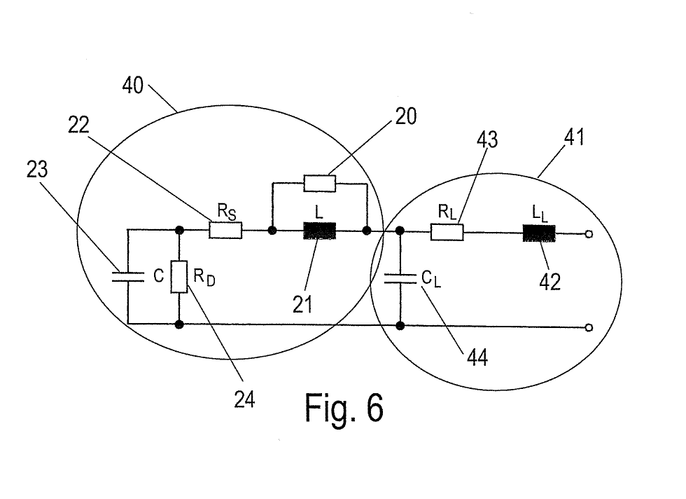

FIG. 6 shows a third equivalent circuit as further matching of an equivalent circuit (cf. FIG. 3 and FIG. 4) to a type-dependent factor. If a supply-line length of a supply line (not illustrated) exceeds a specific value, and/or if high frequencies (for example above 350 kHz) are considered, then the effect of the supply line may possibly no longer be negligible, and a further partial equivalent circuit 41, for the response of the supply line, is added to the equivalent circuit of the PV generator. In this case, L_{L} represents a further supply-line inductance 42, R_{L} represents a further supply-line resistance 43, and C_{L} represents a further supply-line capacitance 44.

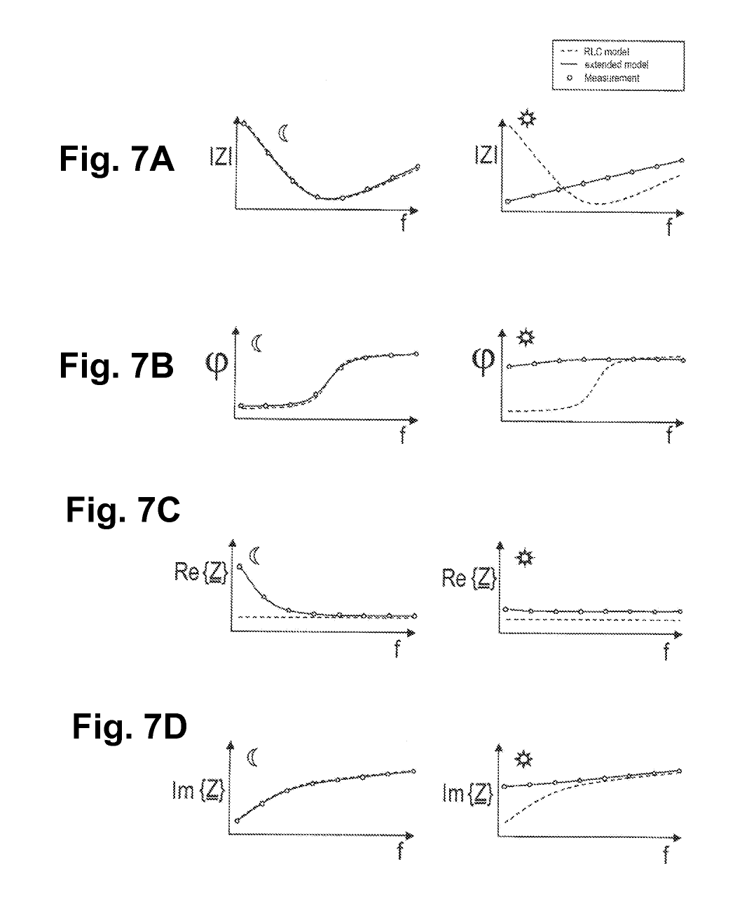

The effect of the matching of an equivalent circuit to the accuracy of determined values is illustrated in FIGS. 7a to 7d, which illustrate examples of diagrammatic illustrations of measured values and modelled values of a generator impedance as a function of a frequency, in various operating states.

The figures show the profile of the magnitude of the impedance |Z|, of the phase φ, the real part Re{Z} of the generator impedance Z_{PV} and the imaginary part Im{Z} of the generator impedance Z_{PV} over a frequency f, in each case without solar radiation (left-side of the figures—moon symbol) and with solar radiation (right-hand side of the figures—sun symbol). The figures also show the comparison of profiles which were each determined from measured values (circular measurement points) of two fundamental models, which will be described in the following text.

The illustration in FIGS. 7a-7d is based on a PV module or a PV generator comprising the same types of cells, in each case in the same operating state. The supply-line resistance 20 (see FIG. 4) in this example is sufficiently high in order to allow it to be ignored, for example because the line length is sufficiently short. The generator resistance R_{D} 24 is likewise comparatively high at night. If the aim is to model only the profile of the magnitude of the impedance |Z| of the phase φ or of the imaginary part Im{Z} of the generator impedance Z_{PV} at night, then it may be possible to ignore the generator resistance R_{D} 24. This results in a simplified so-called RLC approach, that is to say the alternating-current response is modelled by means of an equivalent circuit which consists of a resistance, an inductance and a capacitance connected in series. The RLC model results in a profile of the generator impedance Z_{PV} which is represented by the dashed lines.

Since the resistance value R_{D} will fall drastically during the daytime, based on previous experience, the real response during the daytime can in this case no longer be modelled by a simple RLC approach, and it is impossible to monitor the generator by means of characteristic variables of the basic equivalent circuit. In contrast, if the generator resistance R_{D} 24 is considered within an extended model (identified by the solid lines in FIG. 7), corresponding to the equivalent circuit from FIG. 3 and FIG. 4, the alternating-current response can be described sufficiently accurately both during the daytime (in the presence of solar radiation and in different operating states) and at night. This allows the generator to be reliably monitored, independently of the operating state, even during the daytime. For example, this makes it possible to determine the series resistance R_{S} 22 continuously even during the daytime, and to trigger an alarm signal if a predetermined limit value is exceeded.

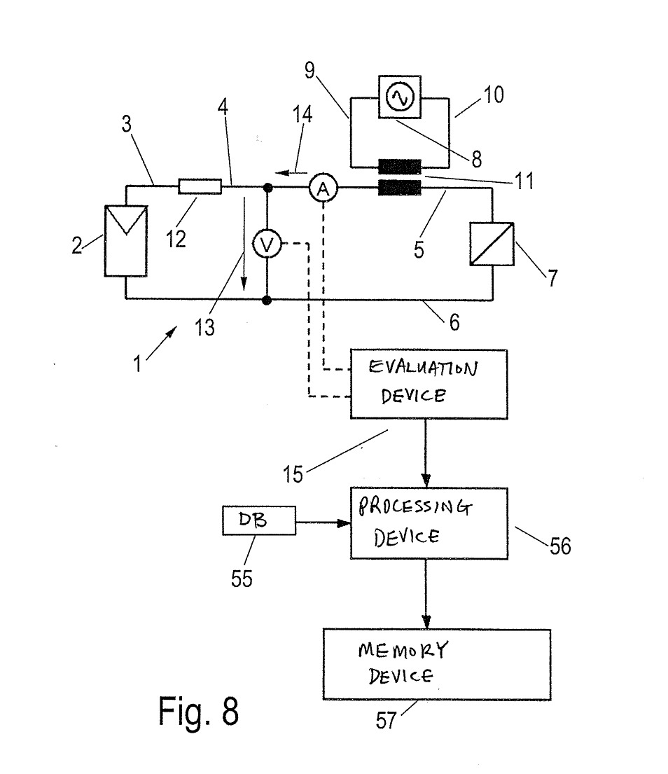

In order to identify the model parameters which are used for the modelling and calculation as described above, it is first of all necessary to measure the complex-value generator impedance Z_{PV}. DE 10 2006 052 295 B3 discloses a circuit arrangement which is suitable for this purpose. In this context, in order to identify the parameters of the equivalent circuits described above, FIG. 8 shows an example of a block diagram of an electrical system having a photovoltaic system 1, with one exemplary embodiment of an apparatus according to the invention for monitoring of contacts of the photovoltaic system 1.

The majority of FIG. 8 corresponds to FIG. 1, but with one output of the measurement and evaluation device 15 being connected to a processing device 56. The measurement and evaluation device 15 is used to determine the generator impedance Z_{PV}. The processing device 56 determines the individual parameters and can be linked to a data base (DB) for expert knowledge 55, for example a data processing system. After identification of the parameters, these parameters are transferred to a further-processing and memory device 57, where they are stored and/or are evaluated using a diagnosis algorithm for monitoring of the contacts of the photovoltaic system 1. Appropriate outputs, for example, alarm signals and/or reports, can then be produced for superordinate monitoring control centres. A cell group in which faults have been identified can likewise be disconnected or switched off, in order to prevent further faults, or possible damage resulting from them.

In one embodiment phase information is employed in addition to the magnitude of the generator impedance Z_{PV} in order to calculate the model parameters. However, alternatively, it is also possible to measure the real part Re{Z} and/or the imaginary part Im{Z} of the generator impedance Z_{PV} (which likewise include the phase information), or any desired combinations. By way of example, in order to identify contact ageing, the model approach in the example of the second equivalent circuit shown in FIG. 4 can be used to determine the series resistance Rₛ solely from the real part Re{Z} of the generator impedance Z_{PV}, over three measured values of the frequency response. All the sought parameters of the proposed equivalent circuits can be calculated using a non-linear search process, with the aid of a quality criterion, which is set up individually and is possibly weighted.

The invention is not restricted to the described exemplary embodiments, and can be modified in many ways. In particular, it is possible to embody the features in combinations other than those mentioned.

Relevant characteristic values for an equivalent circuit can, of course, be determined not only as described in accordance with the known method, but also using further methods.

For example, the values of the magnitude of the generator impedance Z_{PV} and φ as well as Re{Z} and Im{Z}, as well as the corresponding frequency values determined or calculated by means of the measurement and evaluation device 15, can be processed further using expert knowledge 55, by means of the processing device 56, which is designed to process expert knowledge 55, and taking account of an equivalent circuit, and can be used to determine characteristic values.

If necessary, ambiguities can be avoided and the parameter area can be restricted by skilful formulation of expert knowledge 55 into secondary conditions.

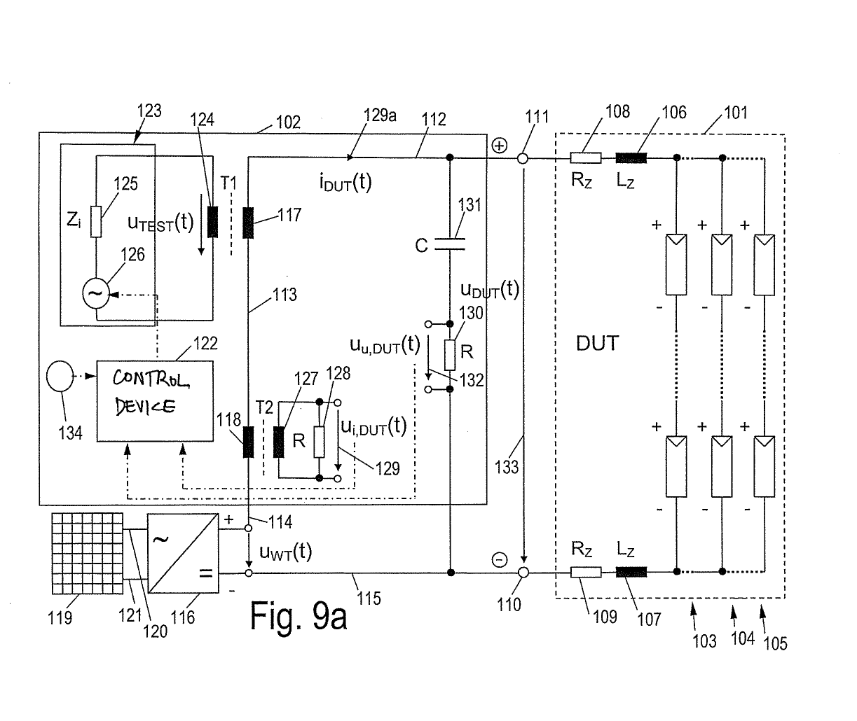

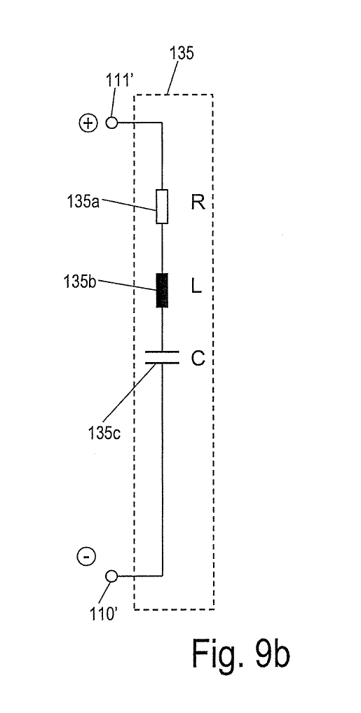

FIG. 9a shows a simplified electrical circuit diagram of an electrical system having a photovoltaic system with a further exemplary embodiment of an apparatus according to the invention. The photovoltaic system 101 (also referred to as DUT, Device Under Test) is monitored by means of a method according to the invention, which can be carried out by an apparatus 102 according to the invention.

The photovoltaic system 1 has a number of photovoltaic modules 103 . . . 105 (so-called strings), only three of which are shown here, and which are connected in accordance with existing requirements. The photovoltaic system 101 has line inductances L_{Z} 106, 107 and line resistances R_{Z} 108, 109.

A negative connecting terminal 110 of the photovoltaic system 101 is electrically connected via an electrical conductor 115 to a negative DC voltage input of an inverter 116. A positive connecting terminal 111 of the photovoltaic system 101 is correspondingly connected via electrical conductors 112, 113 and 114 to a positive DC voltage input of the inverter 116. A secondary winding 117 of a transformer T1 and a primary winding 118 of a transformer T2 are connected into the positive jump 111, 112, 113, 114). The windings are designed such that they do not significantly influence the method of operation of the photovoltaic system 101, in particular with regard to the losses which occur. The function of the transformers T1 and T2 will be explained in detail later. One of the two transformers T1, T2 or both can likewise be connected in the negative jump of the photovoltaic system 101.

The inverter 116 is connected by electrical conductors 120, 121 to an electrical grid system 119, for example to the public electricity grid system, in order to convert an electrical power, which has been produced in the form of a DC voltage by the photovoltaic system 101, in accordance with existing requirements, and to feed it into the electrical grid system 119.

An apparatus 102 is used to monitor the photovoltaic system 101 and has a signal generator 123 which can be driven by a control device 122 and feeds a test voltage u_{TEST}(t) via a primary winding 124 into the direct-current circuit (101, 111, 112, 113, 114, 115, 110). The signal generator 123 has an internal impedance Zᵢ 125 and a controllable source 126, which can be controlled by the control device 122 and which in this case is a voltage source.

For metrological detection of the reaction of the photovoltaic system 1 (DUT) to the test voltage u_{TEST}(t), a voltage u_{i,DUT}(t) 129 is output via a secondary winding 127 of the transformer T2 and via a resistor R 128 connected in parallel with it, which voltage allows metrological detection of the current i_{DUT}(t) 129a, if the transfer function of the arrangement T2 and the resistor 128 is known. The voltage u_{i,DUT}(t) 129 is passed to the control device 122 (dashed-dotted lines), where it is processed further. Furthermore, a voltage u_{u,DUT}(t) 132 is output via a measurement element which is connected in parallel with the terminals 110 and 111, in this case an RC element which includes a resistor 130 and a capacitance 131, which voltage allows metrology detection of the voltage u_{DUT}(t) 133 if the transfer function of the measurement element is known, in this case of the RC element which includes the resistor 130 and the capacitance 131. The voltage u_{u,DUT}(t) 132 is likewise passed to the control device 122 (dashed-dotted line), where it is processed further. A radiation sensor 134 is furthermore optionally connected to the control device 122, providing the control device 122 with information as to whether it is currently daytime or night-time. Alternatively, this information can also be determined from a clock time or from the photocurrent from the photovoltaic system 101.

In one advantageous refinement of the invention, the apparatus 102 including the signal generator 123 and the control device 122 may be integrated in the housing of the inverter 116, or it is likewise feasible for these components to be arranged entirely or partially outside the housing of the inverter 116.

FIG. 9b illustrates a simplified equivalent circuit of a photovoltaic system 101 which was defined in the course of the development work relating to the present invention, specifically that an electrical response of the photovoltaic system 101 can be modelled by means of a circuit 135 comprising a resistance R 135a, an inductance L 315b and a capacitance C 135c. An arrangement such as this, which is annotated with the reference symbol 135, is referred to as a series resonant circuit. A series resonant circuit as described above can therefore be used as an electrical equivalent circuit of a photovoltaic system 101. The equivalent circuit then behaves—within certain limits—electrically identically to the photovoltaic system 101 being modelled by it. In particular, the electrical behaviour of a photovoltaic system 101 when it is dark can be modelled by means of a series resonant circuit 135, that is to say when the photovoltaic system 101 is not subject to any radiation from the sun.

The total impedance of the series resonant circuit 135 is the complex sum of the inductive reactance 135b, of the capacitive reactance 35c and of the resistance 135a. At resonance, that is to say when the series resonant circuit is at the resonant frequency, the capacitive and inductive reactances cancel one another out, leaving the resistance 135a. In summary, the invention proposes that the resistance 135a of the series resonant circuit 135 be determined at the resonant frequency, and that a statement relating to the state of the contacts of the photovoltaic system 101 then be made on the basis of the determined resistance 135a.

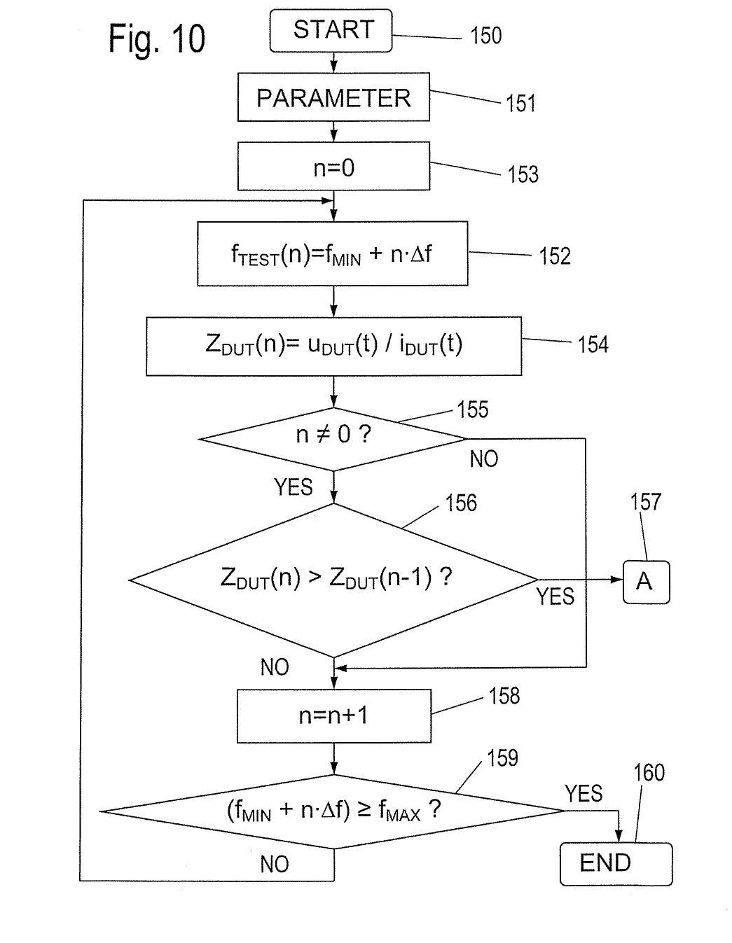

This will be explained in detail in the following text with reference to FIG. 10, which illustrates an example of a flowchart for a method according to the invention.

The individual steps of the flowchart may be stored, for example in the form of a computer program, in a microcomputer device, which is not illustrated, for the control device 122 (cf. FIG. 9).

The illustration shows the process for a measurement cycle. For the purposes of the present invention, a measurement cycle means the application of a test voltage u_{TEST}(t) to the DUT, with the frequency of the test voltage u_{TEST}(t) being increased in steps by a step width Δf up to a maximum frequency f_{MAX} starting from a minimum frequency f_{MIN}.

In a START act 150, the control device 122 starts a measurement cycle. In a further act 151, parameters are defined for the present measurement cycle, for example—depending on the type of photovoltaic system 101 to be monitored—being read from a look-up table in the control device 122. This relates in particular to the parameters f_{MIN}, f_{MAX}, Δf and an amplitude u of a test signal at a test voltage u_{TEST}(t). Further parameters may be defined in this act, if required.

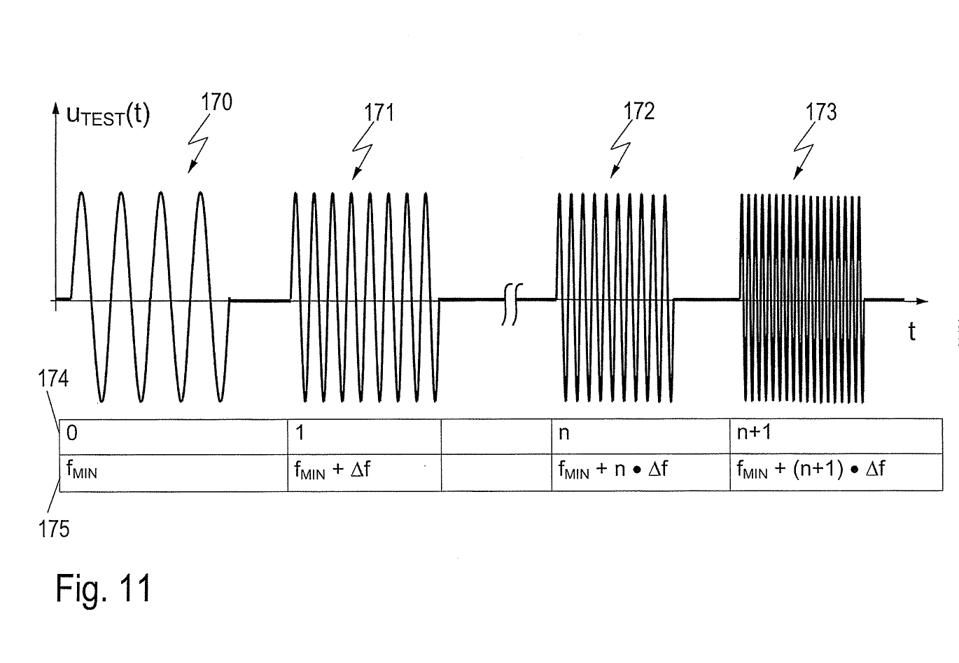

Reference will now be made to FIG. 11 in order to explain the test voltage u_{TEST}(t). By way of example a test voltage u_{TEST}(t) is shown in the form of a voltage/time diagram with various frequencies. The illustration shows a number of oscillation excitations 170, 171, 172 and 173, in this case in the form of sinusoidal excitations. The frequency of the oscillation excitations increases from left to right. A value of the counter n is shown in the line 174, and a calculation rule for calculation of the instantaneous frequency of the instantaneous oscillation excitation is shown in the line 175, based on the known parameters and the corresponding value of the counter n. This results in a test signal comprising a number of oscillation excitations whose frequency increases in steps. If required, time pauses can likewise be defined between the oscillation excitations, and can be varied.

Reference will now once again be made to FIG. 10. In the next act 153, a counter n is set to zero. At 153, the frequency for the first oscillation excitation (cf. FIG. 11) is defined based on the count n. At 154, the equation Z_{DUT}(n)=|u_{DUT}(n)|/|i_{DUT}(n)| is used to determine the magnitude of the instantaneous impedance Z_{DUT}(n), that is to say the impedance Z_{DUT}(n) for the instantaneous frequency value f(n). Z_{DUT}(n), f(n) and possibly the effective values or amplitude values u_{DUT}(n) and i_{DUT}(n) of the measured instantaneous values u_{DUT}(t) and i_{DUT}(t) are stored for calculations in the subsequent acts, for example in a memory device, which is not illustrated, in the control device 122 (cf. FIG. 9). A check is carried out at 155 to determine whether the counter n is equal to zero. In this case, the subsequent query 156 is jumped over, since the number of values for Z_{DUT}(n) in the memory is still not sufficient for comparison of two impedances Z_{DUT}(n). If the value n is greater than zero, a query is carried out at 156 to determine whether the instantaneously measured value for Z_{DUT}(n) is greater than the previously measured and stored value Z_{DUT}(n−1). In the situation where this condition is satisfied, it is assumed that the instantaneous frequency is in the vicinity (the accuracy depends on the value chosen for the parameter Δf) of the resonant frequency of the equivalent circuit, that is to say of the series resonant circuit 135 which models an electrical behaviour of the photovoltaic system 101 to be monitored. Since the impedance Z of a series resonant circuit 135 corresponds to its resistance when it is excited with a signal which is at its resonant frequency, the three most recently determined impedance values Z_{DUT} are used to determine the inductive reactance 135b, the capacitive reactance 135c and the resistance 135a. The resistance of the direct-current circuit of the photovoltaic system 101 to be monitored is now available, that is to say when jumping takes place to A 157 (YES at 156), and this resistance can be processed further and evaluated at A 157. This will also be described in detail further below.

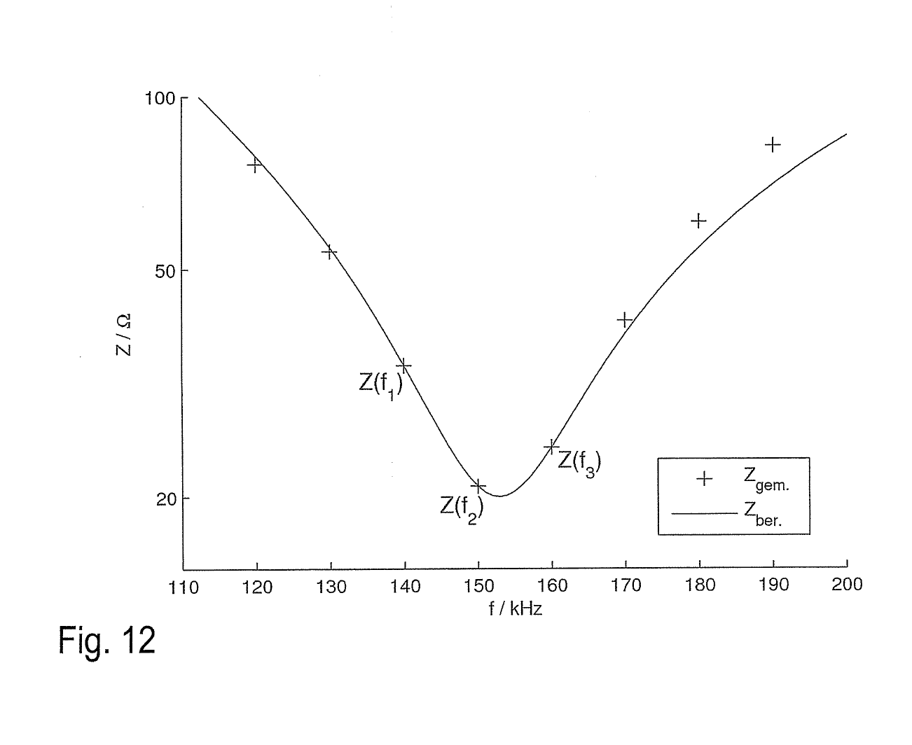

Reference will now be made to FIG. 12 in order to explain the above statements. By way of example, this figure shows an illustration of measured and calculated values of a profile of an impedance Z of a series resonant circuit 135 as a function of a frequency in the form of a diagram. This clearly shows the known profile of the impedance Z, which is a minimum in the region of the resonant frequency (that is to say in the region of Z(f₂)) and rises to the left and right, that is to say below and above the resonant frequency. If Z(f₂) is compared with Z(f₃) in step 156 (cf. FIG. 2), then it will be found that the most recently measured impedance Z(f₃) will be greater than the previously measured impedance Z(f₂). This leads to the deduction that the minimum impedance has just been passed through and it is therefore possible to accurately determine the inductive reactance 135b, the capacitive reactance 135c and the resistance 135a.

If the comparison at 156 in FIG. 10 leads to the conclusion that the instantaneously measured value of the impedance Z_{DUT}(n) is less than the previously measured value Z_{DUT}(n−1), then the instantaneous frequency is not yet in the region of resonance, hence a further run is required. In the next act, the counter n is incremented by 1, and a check is carried out at 159 to determine whether a maximum frequency f_{MAX} of the test signal has been exceeded with the new count. If this is the case (YES at 159), then a jump is made to the end 160 of the instantaneous measurement cycle, possibly with a fault message and/or further steps. If this is not the case (NO at 159), then a jump is made to a new run above at 152, where, as already stated, the instantaneous frequency of the test signal is incremented by a step Δf.

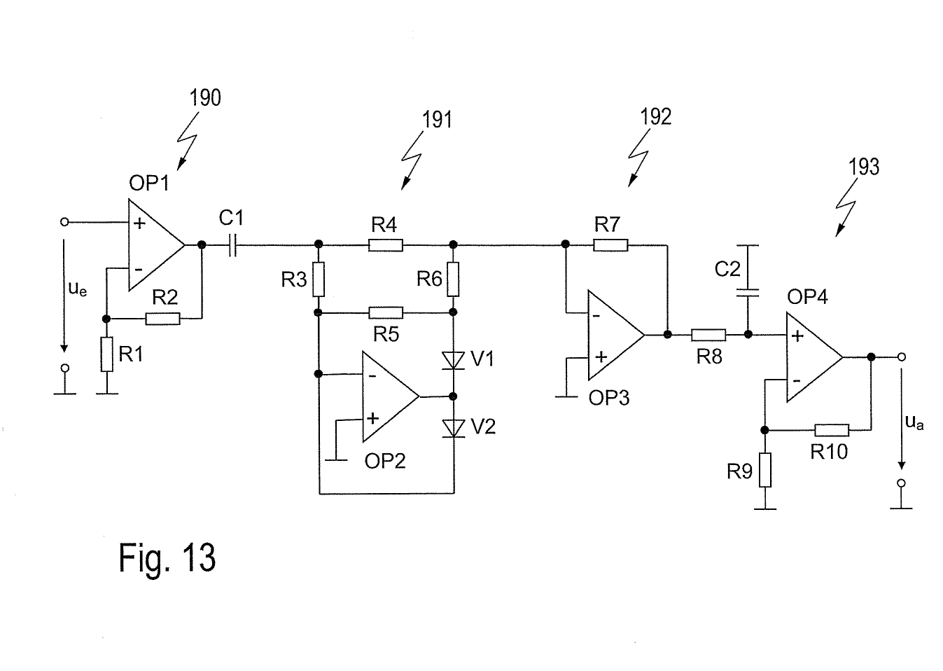

Reference will now be made to FIG. 13, which, by way of example, shows a circuit for preprocessing of the measured voltages u_{u,DUT}(t) 132 and/or u_{i,DUT}(t) 129 (cf. both in FIG. 9). By way of example, the circuit may be arranged in the control device 122 (FIG. 9). The voltage u_{u,DUT}(t) 132 or u_{i,DUT}(t) 129 (cf. both in FIG. 9) is now applied to the input of the circuit uₑ, with the output of the circuit uₐ being connected, for example, to an analogue/digital converter (not shown) for the control device 122.

An assembly 190 has an operational amplifier OP1 and associated circuitry R1 and R2. The assembly 190 represents a non-inverting amplifier for level matching of the input signal uₑ, and the AC voltage component of the output signal from this assembly is coupled via a capacitor C1 to a downstream assembly 191. The assembly 191, with an operational amplifier OP2 and its circuit R3, R4, R5, R6, V1 and V2, together with the assembly 192 and its circuitry R7, represents a rectifier. Averaging is then carried out by means of the low-pass filter R8 and C2 in order to smooth the signal. The level of the output signal uₐ is once again matched to a downstream device by means of the assembly 193 with an operational amplifier OP4 and its circuitry R9 and R10, for example, as already stated, with this level being matched to an analogue/digital converter which is not illustrated.

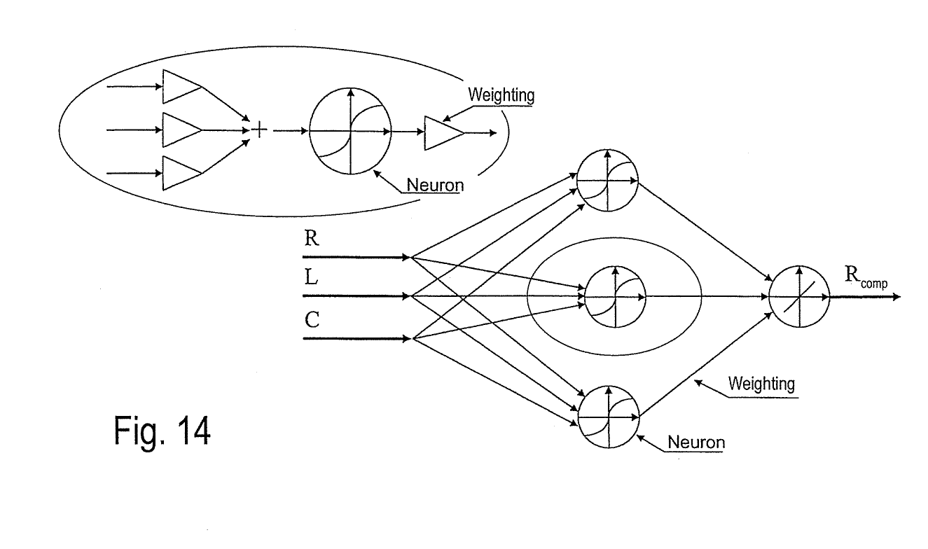

FIG. 14 shows an option for providing temperature compensation, which may be required, for a resistance value that has been determined, by means of a neural network. The figure shows a neural network with the inputs R, L and C. These values are used in order to make a statement about a correction, which may be required, to a determined resistance value without an actual temperature measurement. A determined resistance value can thus be corrected if required using a correction value determined by means of the neural network.

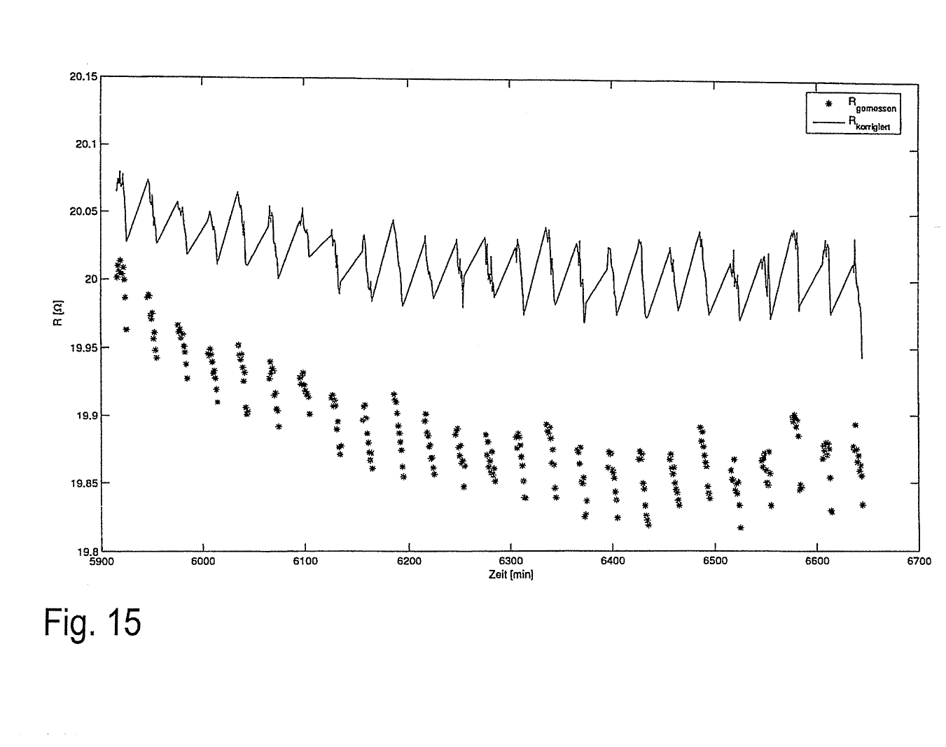

By way of example, FIG. 15 shows a profile of measured resistance values (lower profile) and a profile of resistance values which have been matched by means of a neural network (upper profile). While the measured resistance value (*) varies between 19.82 Ohms and 20.02 Ohms, the corrected values (solid line) are in a narrow range between 19.97 Ohms and 20.08 Ohms.

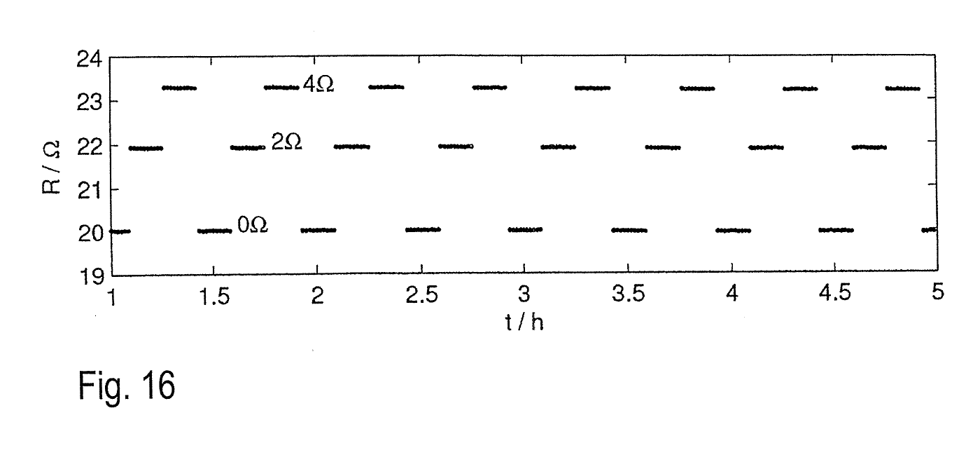

FIG. 16 shows an illustration of discrete resistance values which were determined by means of the invention. Additional resistances of respectively 0 Ohms, 2 Ohms and 4 Ohms were in each case connected for a short time period into the direct-current circuit of a photovoltaic system to be monitored, over a time period of five hours, in order to simulate a contact fault. The illustrated profile of the measured resistances clearly shows the identification accuracy of the method according to the invention.

The determined resistance value for the impedance Z in the region of resonance of a photovoltaic system 101 (DUT, cf. FIG. 9) allows conclusions, inter alia, relating to the state of the circuit of the photovoltaic system 101, in particular of the contact resistances, and of the connecting lines as well. If the resistance R (resistance 135a) of a photovoltaic system 101 (DUT) increases, then this can be used to deduce that the contact resistances have increased, and a warning can be output, disconnection can be carried out and/or the photovoltaic system 1 and its circuitry, to be precise lines and connections, can be checked.

The embodiments described above are only by way of example and do not restrict the invention. It can be modified in many ways within the scope of the claims.

For example, the test signal may have a different oscillation form, for example a square-wave, a triangular-wave, or the like.

It is also feasible to be able to input and output the test signal by means of a single transformer.

The control device 122 may also have an evaluation device which can use the determined values over relatively long time periods to characterize further characteristics of the photovoltaic system 101, such as ageing of the components.

With regard to the above description of preferred exemplary embodiments, it should be noted that a number of preferred refinements are also described in detail in the following text, but that the invention is not restricted to these refinements but can be configured in a varied form as required within the scope of the claims. In particular, terms such as “top”, “bottom”, “front” or “rear” should not be understood as being restrictive, but relate only to the respectively described arrangement. Furthermore, when individual components are explained, these can in principle also be configured in many ways, unless stated to the contrary. Furthermore, the scope of protection also includes specialist modifications of the described arrangements and methods, as well as equivalent refinements.

What is claimed is:

1. A method for diagnosis, in particular monitoring of contacts, of a photovoltaic system, comprising:
injecting a test signal, which comprises a plurality of frequencies, into the photovoltaic system;
determining a generator impedance of the photovoltaic system by evaluating a response signal associated with the test signal; and
monitoring contacts of the photovoltaic system independently of operating states of the photovoltaic system by modelling an alternating-current response of the photovoltaic system based on the determined generator impedance, wherein the modelling is specific to at least two different operating states of the photovoltaic system.

2. The method according to claim 1, wherein the operating states comprise one or more of the following: solar radiation onto a PV generator or onto a part of a PV generator, a temperature of a PV generator or a temperature of a part of a PV generator, or an operating point of a PV generator or of a part of a PV generator.

3. The method according to claim 1, wherein the modelling is based on a magnitude and a phase information relating to the determined generator impedance.

4. The method according to claim 1, wherein the alternating-current response of the photovoltaic system is modelled based on an equivalent circuit, with the monitoring being carried out by means of a characteristic variable of the equivalent circuit, wherein the characteristic variable has a value which is substantially independent of operating states of the photovoltaic system.

5. The method according to claim 4, wherein the equivalent circuit comprises a supply-line inductance, a series resistance and a generator capacitance with a parallel generator resistance, connected in series with the supply-line inductance and the series resistance.

6. The method according to claim 5, wherein the photovoltaic system is modelled by means of a value of the series resistance.

7. The method according to claim 5, wherein the equivalent circuit also comprises a partial equivalent circuit for modelling of a long supply line, which has another supply-line inductance and another supply-line resistance connected in series with the supply-line inductance, as well as a supply-line capacitance in parallel with the generator capacitance.

8. The method according to claim 5, wherein the equivalent circuit comprises a plurality of series-connected pairs of parallel generator capacitances and generator resistances.

9. The method according to claim 8, wherein each pair of parallel generator capacitances and generator resistances model a part of the photovoltaic system which is in the same operating state.

10. The method according to claim 8, wherein each pair of parallel generator capacitances and generator resistances model a part of the photovoltaic system which is of the same type.

11. The method according to claim 5, further comprising another supply-line resistance connected in parallel with the supply-line inductance in the equivalent circuit.

12. The method according to claim 4, wherein at least one partial equivalent circuit comprises a component which takes account of a temperature.

13. The method according to claim 1, wherein contacts of the photovoltaic system are monitored with the aid of expert knowledge associated with a data base.

14. Apparatus for monitoring of contacts of a photovoltaic system, comprising:
a function generator configured to generate a test signal with a definable number of oscillation excitations at different frequencies;
an injection device coupled to the function generator, and configured to inject the test signal into the photovoltaic system;
a device configured to determine a frequency-dependent generator impedance of the photovoltaic system from a response signal associated with the test signal upon the test signal being injected into the photovoltaic system;
at least one processing device configured to identify parameters and monitor contacts of the photovoltaic system by modelling the frequency-dependent generator impedance of the photovoltaic system, wherein modelling is specific to at least two different operating states of the photovoltaic system.

15. The apparatus according to claim 14, wherein the at least one processing device comprises an evaluation device for characterization of at least one property which is representative of ageing of components of the photovoltaic system.

16. The apparatus according to claim 14, wherein the apparatus is integrated in an inverter in the photovoltaic system.
